(19) United States
(12) Patent Application Publication
(10) Pub. No.: US 2024/0295829 A1
(43) Pub. Date: Sep. 5, 2024

(54) PERFORMANCE MANAGEMENT OF SEMICONDUCTOR SUBSTRATE TOOLS

(71) Applicant: Onto Innovation Inc., Wilmington, MA (US)

(72) Inventor: Xin Song, Wilmington, MA (US)

(21) Appl. No.: 18/574,554

(22) PCT Filed: May 24, 2023
(86) PCT No.: PCT/US2023/067414

§ 371 Date: Dec. 27, 2023

Related U.S. Application Data
(60) Provisional application No. 63/346,358, filed on May 27, 2022.

(51) Int. Cl. G03F 7/00

(52) U.S. Cl. CPC G03F 7/706841; G03F 7/70608; G03F 7/706845

(57) ABSTRACT

Proactive management of semiconductor substrate tools. A machine learning model is used to predict future performance characteristics for such tools. In some examples, the model can diagnose issues with tools or with ambient conditions of the tools' environment. In some examples, the model can recommend one or more remedial actions to maintain adequate performance of the substrate tool.

This application is being filed on May 24, 2023, as a PCT International Patent application and claims the benefit of and priority to U.S. Provisional patent application Ser. No. 63/346,358, filed May 27, 2022, the entire disclosure of which is incorporated by reference herein in its entirety.

### FIELD OF DISCLOSURE

The present disclosure is directed to semiconductor component manufacturing and managing performance of tools involved in the semiconductor component manufacturing process.

### BACKGROUND

Semiconductor substrates are manufactured or fabricated as part of the formation of semiconductor chips or other types of integrated circuits (ICs). The components of the ultimate IC may be incorporated into the substrate through a series of fabrication steps. The fabrication steps may include deposition steps where a thin film layer is added onto the substrate. The substrate then may be coated with a photoresist and the circuit pattern of a reticle may be projected onto the substrate using lithography techniques. Etching processes, with etching tools may then occur.

For the completed substrate (e.g., a wafer, or a wafer lot) to be usable, each tool involved in the substrate fabrication process must perform within a predefined acceptable operation tolerance for the aspect of the substrate for which that tool is responsible. If even a single tool in the fabrication process is performing outside of its tolerance, a defect in the substrate of sufficient magnitude can result that requires all of the wafers in that run or subsequent fabrication run to be discarded. Over time and through use (e.g., with each successive fabrication run), the operating performance of a given fabrication tool can degrade or drift, such that the tool eventually requires recalibration in order to perform within specification.

### SUMMARY

In general terms, the present disclosure is directed to proactive maintenance of semiconductor substrate tools (also referred to herein as, simply, tools). Substrate tools can include, for example, and without limitation, fabrication tools (such as deposition tools, lithography tools, oxidation tools, epitaxial reactors, diffusion tools, ion implantation tools, etching tools, and chemical mechanical planarization (CMP) tools), inspection tools, dicing tools, grinding tools, polishing tools, metrology and other measuring tools. While the present disclosure may refer in specific examples to certain substrate fabrication tools (such as deposition tools), the features of the present disclosure can be readily applied to other substrate tools that do not perform fabrication functions.

In further general terms, the present disclosure is directed to improving consistency of performance across substrate tools of the same type.

Features of the present disclosure can be implemented as systems, computer-implemented methods, and as instructions stored on non-transitory computer readable storage.

According to certain aspects, the present disclosure is directed to using a machine learning model to predict a future state of a substrate tool.

According to certain aspects, the present disclosure is directed to using a machine learning model to predict an underperformance of a substrate tool.

According to further aspects, the present disclosure is directed to using a machine learning model to diagnose a cause of a substrate tool's underperformance or predicted underperformance.

According to further aspects, the present disclosure is directed to using a machine learning model to diagnose a cause of a discrepancy or a predicted discrepancy in performance between substrate tools of the same type.

According to further aspects, the present disclosure is directed to using a machine learning model to determine an adjustment of a substrate tool to correct for a predicted underperformance of the substrate tool.

According to further aspects, the present disclosure is directed to using a machine learning model to determine an adjustment of a substrate tool to reduce a performance discrepancy between the substrate tool and another substrate tool of the same type.

According to certain specific aspects, a computer-implemented method for predicting a future performance state of a semiconductor substrate tool following a future use (e.g., a future fabrication run, a future inspection run, a future metrology run) of the tool, includes: providing a current performance state for the fabrication tool to a trained machine learning model; providing operating data for the tool to the trained machine learning model; and receiving the predicted future performance state and a recommended recalibration of the tool, the predicted future performance state and the recommended recalibration being determined by the trained machine learning model based on the current performance state and the operating data.

According to further specific aspects, a computer-implemented method for predicting a future performance state of a semiconductor substrate fabrication tool following a future use (e.g., a future fabrication run, a future inspection run, a future metrology run) of the tool, includes: receiving, by a trained machine learning model, a current performance state for the fabrication tool; receiving, by the trained machine learning model, operating data for the tool; and generating, by the machine learning model, the predicted future performance state and a recommended recalibration of the tool, the predicted future performance state and the recommended recalibration being determined based on the current performance state and the operating data.

According to further specific aspects, a computer-implemented method, includes training a machine learning model to generate a predicted future performance state of a semiconductor substrate fabrication tool and to generate a recommended recalibration of the semiconductor substrate fabrication tool based on a current performance state of the tool and operating data associated with the tool, the operating data including data generated by a sensor associated with the tool or associated with an ambient environment of the tool and data generated by an auto-test performed by the tool.

According to further specific aspects, a computer-implemented method for predicting a predicted future performance state of a substrate tool following a future use (e.g., a future fabrication run, a future inspection run, a future metrology run) of the substrate tool, includes: providing a current performance state for the substrate tool to a trained machine learning model; providing operating data for the substrate tool to the trained machine learning model; and receiving the predicted future performance state and a recommended recalibration of the substrate tool, the predicted future performance state and the recommended recalibration being determined by the trained machine learning model based on the current performance state and the operating data.

According to further specific aspects, a method for predicting a future performance state of a substrate tool following a future use (e.g., a future fabrication run, a future inspection run, a future metrology run) of the substrate tool, includes: receiving, by a trained machine learning model, a current performance state for the substrate tool; receiving, by the trained machine learning model, operating data for the substrate tool; and generating, by the trained machine learning model, a predicted future performance state and a recommended recalibration of the substrate tool, the predicted future performance state and the recommended recalibration being determined based on the current performance state and the operating data.

According to further specific aspects, computer-implemented method, includes: training a machine learning model to generate a predicted future performance state of a substrate tool and to generate a recommended recalibration of the substrate tool based on a current performance state of the substrate tool and operating data associated with the substrate tool, the operating data including data generated by a sensor associated with the substrate tool or associated with an ambient environment of the substrate tool and data generated by an auto-test performed by the substrate tool.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Additional aspects, features, and/or advantages of examples will be set forth in part in the description which follows and, in part, will be apparent from the description, or may be learned by practice of the disclosure.

### BRIEF DESCRIPTION OF THE DRAWINGS

Non-limiting and non-exhaustive examples are described with reference to the following figures.

FIG. 1 schematically depicts an example system for managing performance of a semiconductor substrate tool in accordance with the present disclosure.

FIG. 2 depicts details of a portion of the system of FIG. 1, according to an example embodiment of the system of FIG. 1.

FIG. 3 depicts an example of using a machine learning model to manage performance of a semiconductor substrate tool in accordance with examples of the present disclosure using the system of FIG. 1.

FIG. 4 depicts details of the additional data of FIG. 3, according to an example embodiment of the system of FIG. 1.

FIG. 5 depicts a method of managing performance of semiconductor substrate tools in accordance with examples of the present disclosure using the system of FIG. 1.

### DETAILED DESCRIPTION

Examples of the present disclosure describe systems, methods, and computer-readable products for improving substrate fabrication. More particularly, examples of the present disclosure describe systems, methods, and computer-readable products for improving performance and maintaining improved performance of substrate tools.

An example of such a substrate is a semiconductor wafer, made up of dies. A given wafer has a yield, which can refer to the percentage of dies of the substrate that would meet one or more defined operational, quality, or other acceptability criteria. Defects in the wafer caused by fabrication tools (e.g., a deposition tool, a lithography tool, an etching tool, a CMP tool, and others described above) performing outside of specification (also referred to herein as out of spec) can reduce the yield of the wafer. Depending on the yield and/or type, number and/or severity of defects in the wafer, a wafer, or even an entire lot of wafers from a given fabrication run may have to be discarded, which is costly.

Substrate inspection and measuring tools (e.g., metrology tools) that fall out of spec can cause similar problems, for example, by identifying defects in wafers that are not present, and/or failing to identify defects in wafers that are present.

The present disclosure relates to a systemized approach for substrate tool maintenance. The systemized approach can be readily applied to many different types of substrate tools, such as fabrication tools, inspection tools, metrology tools, and so forth. Advantageously, and regardless of the type of substrate tool, the systemized approach can reduce the amount of time a substrate tool is out of production and/or reduce the number of wafers that have to be scrapped.

In addition, the systemized approach of the present disclosure can improve consistency of performance across different tools of the same type. For example, in the context of fabrication tools, a given fabrication facility may have multiple tools that perform the same fabrication step. Even if all of those tools are within specification (also referred to herein as within spec), there can be discrepancies in performance from tool to tool, which can disadvantageously result in inconsistencies across the completed substrates produced by the facility. Moreover, such inconsistencies can be magnified by performance inconsistences of other tools involved later in the fabrication process.

During substrate fabrication, the substrate undergoes many process steps that are performed by various tools. Such tools can include, for example, and without limitation, deposition tools, etching tools, lithography tools, oxidation tools, epitaxial reactors, diffusion tools, ion implantation tools, and coating tools. The calibration or tuning of each tool is critical to how the tool performs. For example, a deposition tool that is within spec may deposit a 300 angstrom layer on a wafer within a tolerance of 10 angstrom. With each run of the tool (a run can correspond to fabrication of a wafer lot or any other iteration of use for a given type of tool), calibration parameters from the tool can shift due to any of a number of different factors. Inspection and measuring tools are used to inspect and measure aspects of a wafer.

In addition, tools of the same type may both be performing within spec but with discrepancies. For example, a particular deposition tool may be depositing a 300 angstrom layer within spec at 305 angstrom, while another deposition tool may be depositing the same layer at 291 angstrom, resulting in inconsistencies in the final product produced by the facility or fabricator that uses both tools.

According to current methods of tool management and maintenance, each tool is periodically taken out of production for testing and maintenance. In some cases, there is a periodic inspection of wafers fabricated by the tool to see whether the tool is performing within spec and, if not, the tool is taken out of production for maintenance. These methods can be time consuming and costly, and can be both overinclusive and underinclusive in identifying tools in need of maintenance, as some tools are taken out of production prematurely, while other tools are taken out of production only after they are already performing out of spec, requiring wafers to be discarded. Moreover, when a tool begins performing out of spec, the cause and, therefore, the remedy, must be ascertained manually, which can prolong the amount of time the tool is out of production.

According to the present disclosure, a trained machine learning model is used to predict, before a use of a given tool (e.g., before a fabrication run), whether the tool will perform the upcoming (or future) use within spec or outside of spec. Similarly, the model can predict when maintenance will be needed for a given tool. The model can also determine causes of performance discrepancies across tools. In this manner, tool maintenance and management can be performed at a time that minimizes the cost of performing maintenance on a too frequent basis or too infrequent basis.

In addition, the machine learning model is configured to determine the tool parameter(s) that are deviating or beginning to deviate and, thereby, identify and recommend the tool parameter(s) that will require recalibration or other adjustment to keep the tool within spec.

In addition, the machine learning model is configured to perform predictive maintenance modeling for different tool types, by taking into account input data specific to each tool type. Specifically, the model is trained to know how input data correlates with future tool performance and how input data correlates with specific tuning/recalibration needs for specific tools.

In addition, the machine learning model is configured to perform predictive maintenance modeling for different substrate processes (e.g., different deposition steps, different inspection steps) that may be performed by the same tool, by taking into account input data specific to each tool type and specific to the function of each step (e.g., fabrication, inspection, measuring). Specifically, the model is trained to know how input data correlates with future tool performance and how input data correlates with specific tuning/recalibration needs for specific tools performing specific fabrication steps and other substrate functions.

In addition to efficiency improvements in tool maintenance, the present invention can provide for tool-to-tool matching. That is, for a given type of tool (e.g., a tool that performs a specific fabrication step or other substrate function), use of the technology can ensure that all of the tools are operating and will continue operating within a given, predefined tolerance of one another, thereby improving fabrication consistency across tools of the same type. Thus, the machine learning model can take into account current state performance data associated with one or more other tools to determine an appropriate maintenance plan for a given tool of the same type.

According to some examples, the machine learning model is a recurrent neural network (RNN) model. A RNN model can be particularly suited for the present purposes in that a RNN model is configured to take, as part of its input, its previous output, together with further inputs, to generate the next output. As will be described in greater detail herein, according to the present disclosure, the machine learning model is configured to provide, for a given tool, a predicted future performance state for the tool based on various inputs. Those inputs include the previous predicted future state for the tool generated by the model, as well as additional data that may not have been available for the previous model run for the tool. Thus, by using a RNN for tool management in accordance with the present disclosure, for a given tool, each prediction can be based in part on one or more previous predictions for that tool that were taken before previous runs of the tool.

In some examples, the RNN model may be used in combination with one or more convolutional layers.

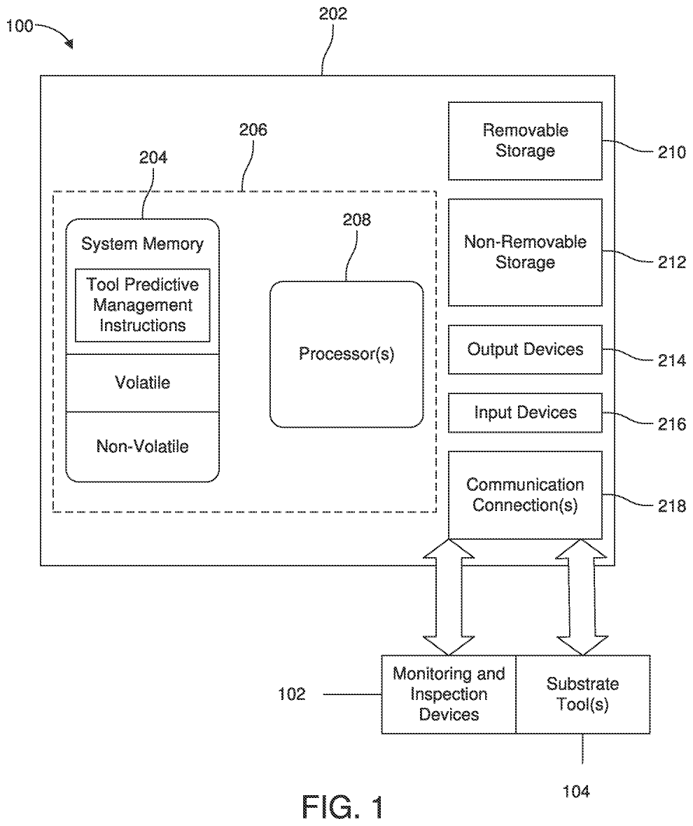

FIG. 1 schematically depicts an example system 100 for managing performance of a semiconductor substrate tool in accordance with the present disclosure.

The system 100 includes a computing device 202. The computing device 202 may be a server and/or other computing device that performs the operations discussed herein, such as the tool management operations described herein. The computing device 202 may include computing components 206. The computing components 206 include at least one processor 208 and memory 204. The memory 204 can include a non-transient computer readable medium. Depending on the exact configuration, the memory 204 (storing, among other things, tool management instructions and other instructions to perform the other operations disclosed herein) can be volatile (such as RAM), non-volatile (such as ROM, flash memory, etc.), or some combination of the two. The computing device 202 may include one or more graphics processing units (GPUs) configured to expedite model training and/or model predictions. Further, the computing device 202 may also include storage devices (removable 210, and/or non-removable 212) including, but not limited to, solid-state devices, magnetic or optical disks, or tape. Further, the computing device 202 may also have input device(s) 216 such as touch screens, keyboard, mouse, pen, voice input, etc., and/or output device(s) 214 such as a display, speakers, printer, etc. One or more communication connections 218, such as local-area network (LAN), wide-area network (WAN), point-to-point, Bluetooth, RF, etc., may also be incorporated into the computing device 202.

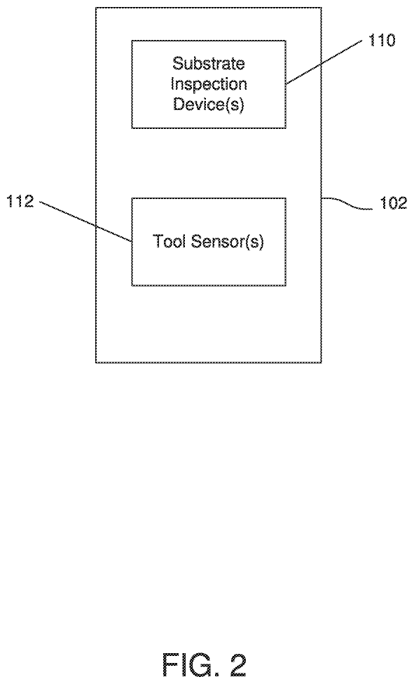

The system 100 can include one or more monitoring and/or inspection devices 102 that is/are in operative communication with, e.g., linked via a network and the communications connection(s) 218 to, the computing device 202. Non-limiting examples of such monitoring and/or inspection devices 102 are shown in FIG. 2. Referring to FIG. 2, the monitoring and/or inspection devices 102 can include, for example, substrate inspection devices 110 and tool sensors 112.

A non-limiting example of a substrate inspection device 110 is a reflectometer or spectrometer that measures intensity of light or other waves (e.g., sound waves) reflected from a substrate at different wavelengths and generates spectra data, from which characteristics of the substrate, such as the thickness of a layer, can be determined. The inspection data can be fed to the machine learning model run on the computing device 202 as input that can be used, in part, by the model, to determine a future state for a tool responsible for the measured characteristic(s).

Non-limiting examples of tool sensor(s) 112 can include temperature sensors, vacuum sensors, light intensity sensors, vibration sensors, ambient light sensors, humidity sensors, optics temperature sensors, fan speed sensors, pressure sensors, flow sensors, electrical current sensors, voltage sensors, and so forth. Data from such sensors can relate to a specific tool parameter, such as the heat or light intensity of the tool's lamp, or the quality of the vacuum chamber generated by the tool. In some examples, data from such sensors can relate to environmental conditions, such as ambient temperature, ambient humidity, ambient light, ambient noise, and so forth. The tool sensor data can be fed to the machine learning model run on the computing device 202 as input that can be used, in part, by the model, to determine a future state for a tool impacted by the sensed condition(s).

The system 100 includes one or more substrate tools 104. The substrate tools 104 can include fabrication tools that perform different substrate fabrication steps such as deposition, lithography, oxidation, diffusion, ion implantation, CMP, and etching for example. The substrate tools 104 can, in addition, or alternatively, include inspection and/or measuring (or metrology) tools. The substrate tool(s) 104 can be linked via a network and the communications connection(s) 218 to, the computing device 202. In this manner, the substrate tool(s) 104 can feed, e.g., tool calibration data to the machine learning model run on the computing device 202 as input that can be used, in part, by the model to determine a future state for the tool.

The substrate tool 104 itself can also provide data relevant to predicted future performance. Alternatively, or in addition, such data for the substrate tool 104 can be obtained by one or more or other tools. Such data can include tool auto-test data, calibration data, and run-time data. For example, a substrate tool can monitor or periodically run a monitoring test on various calibration and other aspects of the substrate tool, such as the alignment of the tool's fabrication stage, a wobble of the tool's fabrication stage, an intensity of a lamp of a tool, a repeatability of an aperture of the tool (e.g., a material deposition aperture or a lens aperture), a video focus of the tool, and so forth. In some examples, the substrate tool 104 itself can feed this auto-monitoring and/or auto-test data to the machine learning model run on the computing device 202 as input that can be used, in part, by the model, to determine a future state of a tool impacted by the sensed condition(s).

Run-time data is captured for each run of the tool, and can therefore be helpful in identifying and tracking small changes in tool performance and when precisely they occur. Examples of run-time data include alignment data and autofocus data for a tool for each use (e.g., each fabrication run) of the tool. In contrast, auto-test data and calibration data can be captured periodically, e.g., as part of a tool health check process. In some examples, auto-test data and calibration data can include types of performance data that are not monitored or present at each tool run and, therefore, would not be included in run-time data. An example of calibration data includes data relating to a calibration performed by the tool.

In alternative configurations, one or more components of the computing device 202 reside locally on the one or more monitoring and/or inspection devices 102 or substrate tools 104. For example, the one or more monitoring and/or inspection devices 102 or the one or more substrate tools 104 can be configured to themselves perform one or more of the machine learning model tool management operations described herein. That is, the machine learning model tool management instructions can be run directly on the one or more monitoring and/or inspection devices 102 or the one or more substrate tools 104.

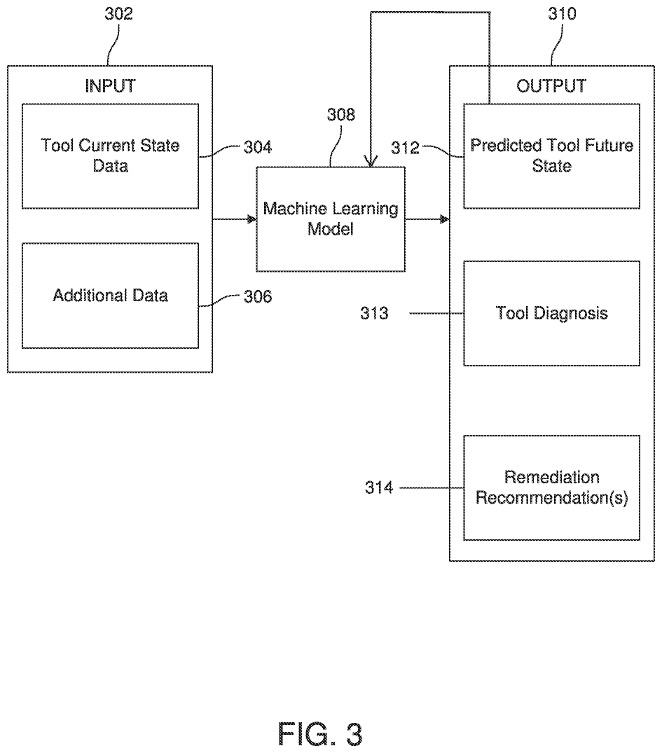

FIG. 3 depicts an example of using a machine learning model to manage performance of a semiconductor substrate tool in accordance with examples of the present disclosure using the system 100 of FIG. 1.

In some examples, one or more of the operations of FIG. 3 can be performed by the computing device 202 and/or the one or more of the monitoring and/or inspection devices 102 and/or the substrate tools 104 of FIG. 1.

Referring to FIG. 3 generally, input 302 is provided to a machine learning model 308. In some examples, the machine learning model 308 is a RNN model. The machine learning model 308 is trained such that the machine learning model 308 is configured to analyze the input 302 to generate an output 310, that can be provided (e.g., displayed on a display device) to a technician using the computing device 202 of FIG. 1. The input 302 can be provided by any of a number of different sources. Examples of such sources can include a substrate tool 104 or monitoring and/or inspection devices 102 (FIG. 1). Input can also be provided from data stored on the computing device 202.

The input 302 can include tool current state data 304 and additional data 306. The tool current state data 304 can include the previous predicted state for a given tool predicted by the machine learning model 308. For instance, for a given deposition tool, modeling can be performed to predict a future state of the tool after each successive use (e.g., substrate fabrication run) for the tool. For each modeling, the output is the predicted state of the tool following the next use of the tool (e.g., the next fabrication run). For each modeling, one of the inputs 302 to the machine learning model 308 is the previously predicted state of the tool predicted by the machine learning model 308 prior to the previous use of the tool (e.g., the previous fabrication run). This input reflects the current state of the tool. That is, this input reflects the tool's current performance level or quality (within spec, out of spec, within spec but with deviation from another tool of the same type, etc.).

In a particular example of a layer deposition tool, this input can reflect, for a particular substrate layer, the thickness of the deposited layer deposited by the tool on the previous use of the tool (e.g., the previous fabrication run). In a particular example of an inspection tool, this input can reflect, for a particular substrate, whether a defect is detected, and/or the nature and severity of the defect. In a particular example of a metrology tools, this input can reflect, for a particular feature such as a transistor or thin film, whether the critical dimension is within specification. In a particular example of a lithography tool, this input can reflect, for a given substrate, an alignment of two layers of the substrate relative to each other. For many different types of substrate tools, this input can reflect, among other things, a critical dimension of one or more structural or functional features of the substrate. Regardless of the substrate tool or the performance aspect of a substrate tool in question, this input data is fed to the machine learning model 308 so that the machine learning model 308 can use the current state of the tool as a baseline set of data from which to predict the next future state of the tool (e.g., the state of the tool after the next use of that tool, such as after the next fabrication run, or after the next metrology run, etc.).

The tool current state data 304 can also include current state performance data for other tools, based on which the machine learning model 308 can perform tool-to-tool performance matching for tools of the same type, by comparing predicted performance of a given tool with current or predicted performance of another tool of the same type.

The input 302 can also include additional data 306. The additional data can include operating data for the tool.

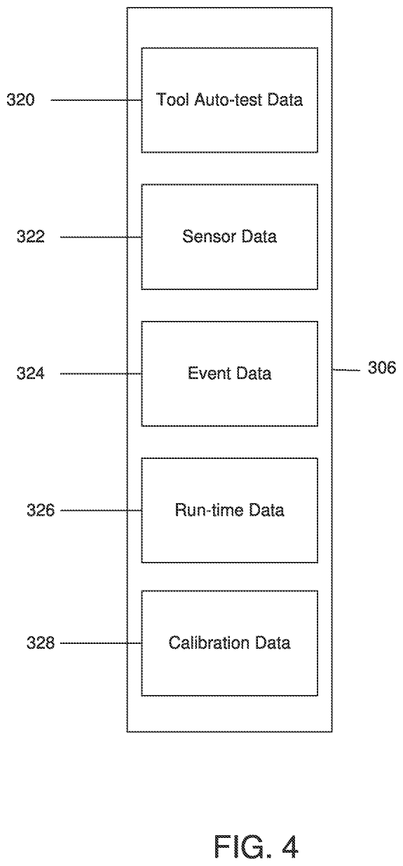

Referring to FIG. 4, the additional data 306 can include current data obtained by the monitoring and/or inspection devices 102 and/or the substrate tool 104 itself (FIG. 1). In some examples, the current data, or some of the current data, is obtained from the most recent fabrication operation of the tool. For example, the additional data 306 can include sensor data 322, including both tool-specific sensor data and ambient condition sensor data. The additional data 306 can also include auto-test data 320 generated by the tool itself. The additional data 306 can also include run-time data 326 obtained from each use (e.g., each fabrication run) of the substrate tool 104. The additional data 306 can also include calibration data 328 (e.g., data relating to calibrations performed by the substrate tool 104).

Referring to FIG. 4, the additional data 306 can also include tool event data 324. Tool event data 324 can be provided to the machine learning model 308 by the tool itself, or via another means or from another device. Event data 324 can include, for example, exceptions that have taken place with respect to the tool in question during a use of the tool (e.g., during a fabrication run), such as the occurrence of an error during a run or a removal of the tool by the tool owner during a run or after a run. For instance, if a tool was removed from fabrication and recalibrated, the relevance of the tool current state data 304 to predict the future state of the tool may be discounted by the machine learning model 308 according to how the model has been trained. Another example of an event can be the replacement of a part or a component of the tool, such as a replacement of a lamp of the tool, a lens of the tool, a stage of the tool, etc.

The machine learning model 308 can be a trained machine learning model that processes the input 302 and generates output 310, based on the input 302. The output 310 can be presented via an interface of a computing device, such as the output device 214 (FIG. 1). For example, the output 310 can be presented as a maintenance or management report for a tool indicating predicted maintenance for the tool. The output 310 can include one or more alerts or alarms. For example, an alert can be generated that a tool is predicted to fall outside of spec at the next use of the tool such that performance recalibration is warranted, or that a tool has deviated in performance more than a predefined threshold magnitude from another tool of the same type, such that tool-to-tool recalibration is warranted.

The output 310 can include a predicted tool future state 312. The predicted tool future state 312 can include a predicted performance metric for a given tool following the tool's next fabrication or other function. In a particular example of a layer deposition tool, this output can reflect, for a particular substrate layer the tool is responsible for fabricating, a prediction of the thickness of the layer to be deposited by the tool at the tool's next use (e.g., at the tool's next fabrication run). In addition, or alternatively, this output can include an indication that the predicted performance of the tool for the next run will be within spec or outside of spec. In addition, or alternatively, this output can include an indication that the predicted performance of the tool for the next run will be less than or more than a predefined maximum threshold deviation from the performance of another tool of the same type.

The output 310 can include a predicted future performance state for the substrate tool. The outputted predicted future performance state can then be provided as input to the trained machine learning model 308 as a subsequent performance state of the substrate tool. A subsequent predicted future performance state of the substrate tool following a subsequent future use (e.g., a future fabrication run) for the substrate tool is determined by the trained machine learning model 308 based on the subsequent performance state of the substrate tool.

The output 310 can include a tool diagnosis 313. A tool diagnosis 313 can indicate a cause for a tool's predicted performance to be outside of spec or for a tool's predicted performance to be greater than a minimum threshold deviation. Non-limiting example diagnoses can include a misaligned stage of the tool, tool optics temperatures that are too high, a stage having too much wobble, lamp intensity that is too high or too low, a fan speed that is too low, an ambient temperature that is too high or too low, variability in aperture repeatability that is too high/low, a variability in video focus that is too high, and so forth. Thus, the diagnosis 313 can relate to a parameter of the tool itself, or to an ambient condition in which the tool is positioned.

The output 310 can include one or more remediation recommendations 314. For example, if it is determined that some maintenance of the tool or the ambient conditions surrounding the tool is warranted based on the predicted tool future state 312 and the tool diagnosis 313, the machine learning model 308 is configured to generate a recommendation for the maintenance. For instance, the recommendation 314 can include a recommendation to lower or raise the ambient temperature or the ambient light, to replace a fan, to adjust the alignment of the tool's stage by a specified amount, to adjust an intensity of the tool's lamp by a specified amount, to replace the tool's optics, to tighten the tool's stage by a specific amount, and so forth.

Advantageously, because the machine learning model 308 ascertains a diagnosis and remedy specific to the diagnosis, the indicated maintenance is targeted and can then therefore be performed more quickly and with less production interruption than, for example, periodic maintenance in which many more aspects of the tool are checked and tested to see if tuning or other recalibration is needed for each one.

In addition, the machine learning model 308 is configured to identify when deviation in performance or poor performance is not a result of the tool's parameters or calibration, but of the ambient environment. For instance, a remedy determined by the machine learning model 308 can be to decrease the ambient temperature of the environment around the tool by a specified number of degrees, which can be an easy and straightforward fix that does not require pulling the tool out of production for any length of time.

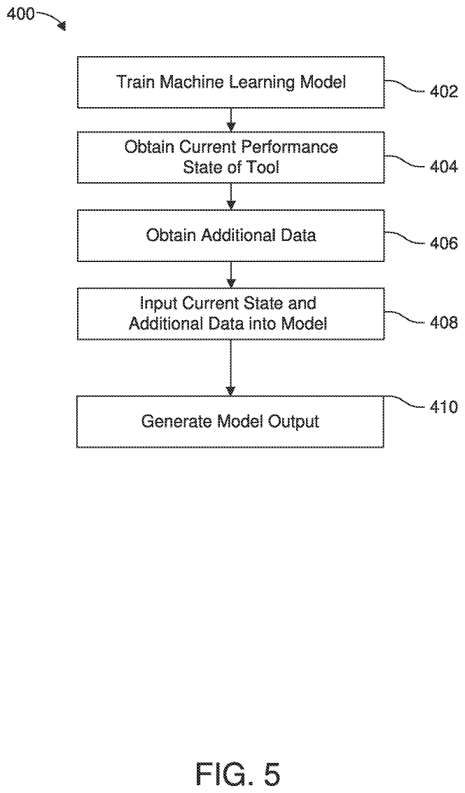

FIG. 5 depicts a method 400 of managing performance of semiconductor substrate tools in accordance with examples of the present disclosure using the system 100 of FIG. 1. It will be appreciated that different embodiments of the present disclosure may include different combinations of subsets of the steps of the method 400, non-limiting examples of which are described herein.

At a step 402 of the method 400, a machine learning model (e.g., the machine learning model 308 (FIG. 3)) is trained for each type of substrate tool using known tool performance data. For a given tool or type of tool, performance data from successive uses (e.g., successive fabrication runs) is processed, as well as the auto-test data, sensor data and event data associated with each fabrication. From this information, the model 308 learns how different factors (such as tool-specific factors, environmental factors, etc.) individually and collectively impact performance of a given tool or tool type over time, causing shifts in performance over successive uses of the tool (e.g., over successive fabrication runs). For example, the machine learning model 308 can learn that for a particular type of layer deposition tool, a lamp intensity of certain magnitude can, depending on other tool and ambient factors, cause the tool's performance to change in a particular way (e.g., the tool's deposition layer thickens).

At the step 402, by processing the training data together with the known tool performance data from many runs of the tools, the machine learning model 308 learns how to predict tool future states, diagnose issues with tools, and recommend remedies to resolve the issues. For example, the model learns to align the relevant data of a target tool with corresponding data of training tools with known outcomes.

At a step 404 of the method 400, the machine learning model 308 obtains the current performance state of the tool. In some examples, the current performance state of the tool is the predicted tool future state 312 (FIG. 3) from the previous run of the model for that tool. In other examples, e.g., if the tool is new or recalibrated since the last model run, the current performance state of the tool can be determined using a substrate inspection device, such as a metrology device. For example, for a layer deposition tool, the current performance state of the tool can be determined by a spectrometer that measures a thickness of the substrate deposition layer from the tool's most recent (or first) run. However, the current performance state of the tool is determined, the data is fed to the model 308 at the step 408.

At a step 406 of the method 400, additional data is obtained. The additional data can include the additional data 306 (FIG. 4) described above. This data can be obtained from the substrate tool 104 and the monitoring and inspection device(s) 102 (FIG. 1) and fed, at the step 408, to the machine learning model 308, as described above.

At a step 410 of the method 400, the machine learning model 308 generates a model output. The model output can include any of the output 310 (FIG. 3) described above. The model output can be provided through any appropriately configured output device, as described above.

The machine learning model 308 (FIG. 3) can be provided with known performance data even after the initial training phase. For example, output predictions of the model following a run of the method 400 can be tested empirically, (e.g., with a substrate inspection device) and the result of the test can be input to the model as additional training data to improve the model's ability to predict recalibration needs for a given tool.

As mentioned, the machine learning model 308 can be trained on a tool type by tool type basis. Calibration parameters, environmental factors, and event occurrences can impact performance of different types of tools in different ways and to different degrees. Thus, at the step 402 (FIG. 5), the machine learning model 308 (FIG. 3) can be trained separately for each tool. In addition, the tool current state data 304 (FIG. 3) can include a type of the tool. The type of the tool is used by the machine learning model 308 to select the appropriate modeling pathway to generate the output 310 for that tool.

In addition, the machine learning model 308 can be trained separately for each fabrication step or other tool function. Calibration parameters, environmental factors, and event occurrences can impact performance of different types of fabrication steps and other tool functions in different ways and to different degrees. Thus, at the step 402 (FIG. 5), the machine learning model 308 (FIG. 3) can be trained separately for each type of fabrication step or other tool function. In addition, the tool current state data 304 (FIG. 3) can include a fabrication step or tool function type. The type of the fabrication step or tool function is used by the machine learning model 308 to select the appropriate modeling pathway to generate the output 310 for that tool.

The embodiments described herein may be employed using software, hardware, or a combination of software and hardware to implement and perform the systems and methods disclosed herein. Although specific devices have been recited throughout the disclosure as performing specific functions, one of skill in the art will appreciate that these devices are provided for illustrative purposes, and other devices may be employed to perform the functionality disclosed herein without departing from the scope of the disclosure. In addition, some aspects of the present disclosure are described above with reference to block diagrams and/or operational illustrations of systems and methods according to aspects of this disclosure. The functions, operations, and/or acts noted in the blocks may occur out of the order that is shown in any respective flowchart. For example, two blocks shown in succession may in fact be executed or performed substantially concurrently or in reverse order, depending on the functionality and implementation involved.

This disclosure describes some embodiments of the present technology with reference to the accompanying drawings, in which only some of the possible embodiments were shown. Other aspects may, however, be embodied in many different forms and should not be construed as limited to the embodiments set forth herein. Rather, these embodiments were provided so that this disclosure was thorough and complete and fully conveyed the scope of the possible embodiments to those skilled in the art. Further, as used herein and in the claims, the phrase “at least one of element A, element B, or element C” is intended to convey any of: element A, element B, element C, elements A and B, elements A and C, elements B and C, and elements A, B, and C. Further, one having skill in the art will understand the degree to which terms such as “about” or “substantially” convey in light of the measurement techniques utilized herein. To the extent such terms may not be clearly defined or understood by one having skill in the art, the term “about” shall mean plus or minus ten percent.

Although specific embodiments are described herein, the scope of the technology is not limited to those specific embodiments. Moreover, while different examples and embodiments may be described separately, such embodiments and examples may be combined with one another in implementing the technology described herein. One skilled in the art will recognize other embodiments or improvements that are within the scope and spirit of the present technology. Therefore, the specific structure, acts, or media are disclosed only as illustrative embodiments. The scope of the technology is defined by the following claims and any equivalents therein.

1. A computer-implemented method for determining a predicted future performance state of a substrate tool, comprising:
providing a current performance state for the substrate tool to a trained machine learning model;
providing operating data for the substrate tool to the trained machine learning model; and
outputting the predicted future performance state of the substrate tool, the predicted future performance state being determined by the trained machine learning model based on the current performance state and the operating data.

2. The computer-implemented method of claim 1, further comprising outputting a recommended recalibration of the substrate tool determined by the trained machine learning model based on the current performance state.

3. The computer-implemented method of claim 1, wherein the operating data includes data generated by a sensor associated with the substrate tool or associated with an ambient environment of the substrate tool.

4. The computer-implemented method of claim 1, wherein the operating data includes data generated by an auto-test performed by the substrate tool.

5. The computer-implemented method of claim 1, wherein the operating data includes data generated by an occurrence of an error associated with the substrate tool.

6. The computer-implemented method of claim 1, wherein the current performance state includes a type of the substrate tool.

7. The computer-implemented method of claim 1, wherein the current performance state includes a type of a fabrication step or a type of another substrate function performed by the substrate tool.

8. The computer-implemented method of claim 1, wherein the trained machine learning model includes a recurrent neural network.

9. The computer-implemented method of claim 1, further comprising:
outputting the predicted future performance state as an outputted predicted future performance state;
providing as input to the trained machine learning model the outputted predicted future performance state as a subsequent performance state of the substrate tool; and
receiving a subsequent predicted future performance state of the substrate tool following a subsequent future use of the substrate tool, the subsequent predicted future performance state being determined by the trained machine learning model based on the subsequent performance state of the substrate tool.

10. The computer-implemented method of claim 1,
wherein the current performance state includes a thickness of a substrate layer; and
wherein the predicted future performance state includes a predicted thickness of a substrate layer, the thickness and the predicted thickness being different.

11. The computer-implemented method of claim 1, wherein the current performance state is determined by a substrate inspection tool.

12. The computer-implemented method of claim 1:
wherein a recommended recalibration includes to recalibrate an identified parameter of the substrate tool before a future use of the substrate tool.

13. The computer-implemented method of claim 12, wherein the identified parameter is a lamp intensity.

14. The computer-implemented method of claim 1, further comprising, receiving a recommendation to adjust a condition of an ambient environment around the substrate tool, the recommendation being generated by the trained machine learning model based on the current performance state and the operating data.

15. The computer-implemented method of claim 1, wherein the predicted future performance state includes an indication that a performance of the substrate tool will be outside of a predefined performance specification for a future use of the substrate tool.

16. The computer-implemented method of claim 1, wherein the predicted future performance state includes an indication that a performance of the substrate tool will deviate from a performance of another tool by more than a predefined maximum deviation on a future use of the tool.

17. A method for predicting a future performance state of a substrate tool, comprising:
means for receiving, by a trained machine learning model, a current performance state for the substrate tool;
means for receiving, by the trained machine learning model, operating data for the substrate tool; and
means for generating, by the trained machine learning model, a predicted future performance state of the substrate tool, the predicted future performance state being determined based on the current performance state and the operating data.

18. The method of claim 17, further comprising:
means for generating, by the trained machine learning model, a recommended recalibration of the substrate tool based on the current performance state and the operating data.

19. The method of claim 17, wherein the operating data includes data generated by one or more of:
a sensor associated with the substrate tool or associated with an ambient environment of the substrate tool;
an auto-test performed by the substrate tool;
run-time data for the substrate tool, the run-time data including data associated with an alignment or an autofocus of the substrate tool;
a calibration performed by the substrate tool; and
an event, the event including a replacement of a component of the substrate tool.

20. The method of claim 17, wherein the operating data includes data generated by an occurrence of an error associated with the substrate tool.

21. A system for determining a predicted future performance state of a substrate tool, comprising:
one or more processors; and
non-transitory computer-readable storage having stored thereon instructions which, when executed by the one or more processors, cause the system to:
provide a current performance state for the substrate tool to a trained machine learning model;
provide operating data for the substrate tool to the trained machine learning model; and
output the predicted future performance state of the substrate tool, the predicted future performance state being determined by the trained machine learning model based on the current performance state and the operating data.

22. The system of claim 21, wherein the operating data includes data generated by an occurrence of an error associated with the substrate tool.
